(19) United States
(12) Patent Application Publication
(10) Pub. No.: US 2012/0052288 A1
(43) Pub. Date: Mar. 1, 2012

(54) FILM STRUCTURE AND METHOD FOR MANUFACTURING THE SAME

(75) Inventors: Huan-Chien TUNG, KAOHSIUNG COUNTY (TW); Jye-Long LEE, KAOHSIUNG CITY (TW); Chun-Hao CHIU, KAOHSIUNG COUNTY (TW)

(73) Assignee: CHINA STEEL CORPORATION, KAOHSIUNG (TW)

(21) Appl. No.: 12/962,636

(22) Filed: Dec. 7, 2010

(30) Foreign Application Priority Data
Aug. 26, 2010 (TW) 099128692

(51) Int. Cl. B32B 5/16; C23C 14/14; C23C 14/35

(52) U.S. Cl. 428/328; 204/192.12

(57) ABSTRACT

A film structure is described. The film structure includes a substrate and a metal film. The film structure is formed on the substrate by a physical vapor deposition method. A bottom diameter of particles forming the metal film is substantially between 0.05 μm and 2 μm, and a height of the particles of the metal film is substantially between 0.05 μm and 3 μm. The metal film has a brightness, a first chroma and a second chroma in a visible light region, which includes a wavelength range between 380 nm and 770 nm, the brightness is substantially between 65 and 95, the first chroma is substantially between −2.1 and 2.1, and the second chroma is substantially between −2.1 and 2.1

### RELATED APPLICATIONS

This application claims priority to Taiwan Application Serial Number 099128692, filed Aug. 26, 2010, which is herein incorporated by reference.

### FIELD OF THE INVENTION

The present invention relates to a film structure, and more particularly to a film structure having a white surface.

### BACKGROUND OF THE INVENTION

As science and technology change with each passing day, requirements for electronic products are increased, wherein the requirements includes compactness, the product case with a metallic texture or the product case with a desired color. The color has to be displayed through light. The spectra of the light can be divided into ultraviolet ray, infrared ray, visible light and light with different energy according to wavelengths or frequencies. The wavelength range of the visible light is from 380 nm to 770 nm, and the visible light can be sequentially divided into red light, orange light, yellow light, green light, blue light and violet light, wherein the wavelength of the violet light is the shortest, and the wavelength of the red light is the longest. While light is the combination of lights with different wavelengths and appropriate energy in visible spectra and is a compound light. By in equivalently combining the lights of various wavelengths in visible spectra or only combining the lights of portions of wavelengths, various white lights can be obtained.

When light falls upon a surface of an object, the light is reflected, absorbed or is transmitted, and the color created in a human eye by the reflected light is the presented color of the object. For example, after white light is divided into various monochromatic lights by passing a triangular prism, and the monochromatic lights are used to illuminate a red glass, the red glass absorbs all of the monochromatic lights but passes the red light, and the human eye only observes the red light. For example, a red apple only reflects the red light and the lights of the other colors are absorbed, so that when the red apple is illuminated by a full spectrum light, the human eye observes the apple being in the red color. However, when the red apple is illuminated by a green light, because there is no or a few of red light for the red apple to reflect, and the green light is almost completely absorbed by the apple, the color of the apple is presented in black or charcoal gray.

If an electronic product having a white case is required, a conventional method uses a spray coating method to coat a white paint film on a metal substrate or an alloy substrate to be the case of the electronic product. However, the paint spraying process for forming the film damages and pollutes the operators and the environment.

Therefore, a white film structure is needed, in which the process of forming a white metal firm of the white film structure does not pollute the environment.

### SUMMARY OF THE INVENTION

Therefore, one aspect of the present invention is to provide a film structure, which is a white film formed by sputtering with the conventional apparatus, so that no special apparatus is needed and no training is needed for the workers, and the manufacturing method can be switched immediately, thereby decreasing the cost of process switch.

Another aspect of the present invention is to provide a film structure. A metal film can be formed as a film with a rough microcosmic structure by controlling diameters of sputtering metal particles. The film structure reflects the incident visible light and the incident infrared ray with high reflectivity, wherein the reflected rays are scattering randomly. In addition, the incident rays can be scattered to any directions by the film structure, so that the film structure is presented with a white surface in the visible light region.

According to the aforementioned aspects, the present invention provides a film structure including a substrate and a metal film, wherein the metal film is formed on the substrate by a physical vapor deposition (PVD) method. A bottom diameter of particles forming the metal film is substantially between 0.05 μm and 2 μm, and a height of the particles of the metal film is substantially between 0.05 μm and 3 μm. The metal film has a brightness, a first chroma and a second chroma in the visible light region (wavelength is between 380 nm and 770 nm). The brightness is substantially between 65 and 95, the first chroma is substantially between −2.1 and 2.1, and the second chroma is substantially between −2.1 and 2.1. A color of the metal film is defined as pure white while the brightness is 100, and a color of the metal film is defined as pure black while the brightness is 0. A color of the metal film is defined as red while the first chroma is a positive value, and a color of the metal film is defined as green while the first chroma is a negative value. A color of the metal film is defined as yellow while the second chroma is a positive value, and a color of the metal film is defined as blue while the second chroma is a negative value. The color of the metal film has more value while the first chroma and the second chroma are getting larger, and the color of the metal film has less value while the first chroma and the second chroma are getting smaller.

According to the aforementioned aspects, the present invention provides a method for manufacturing a film structure, in which the film structure is formed by a physical vapor deposition method. The method includes providing a substrate and depositing a metal film on the substrate by using a metal target. A bottom diameter of particles forming the metal film is substantially between 0.05 μm and 2 μm, and a height of the particles of the metal film is substantially between 0.05 μm and 3 μm. The metal film has a brightness, a first chroma and a second chroma in the visible light region. The brightness is substantially between 65 and 95, the first chroma is substantially between −2.1 and 2.1, and the second chroma is substantially between −2.1 and 2.1. A color of the metal film is defined as pure white while the brightness is 100, and a color of the metal film is defined as pure black while the brightness is 0. A color of the metal film is defined as red while the first chroma is a positive value, and a color of the metal film is defined as green while the first chroma is a negative value. A color of the metal film is defined as yellow while the second chroma is a positive value, and a color of the metal film is defined as blue while the second chroma is a negative value. The color of the metal film has more value while the first chroma and the second chroma are getting larger, and the color of the metal film has less value while the first chroma and the second chroma are getting smaller.

According to a preferred embodiment of the present invention, the physical vapor deposition method is a vacuum DC magnetron sputtering method or a vacuum RF magnetron sputtering method.

According to a preferred embodiment of the present invention, the substrate is a metal substrate, an alloy substrate, a ceramic substrate, a glass substrate, a semiconductor substrate or a plastic substrate.

According to a preferred embodiment of the present invention, the metal substrate is a stainless Steel substrate.

According to a preferred embodiment of the present invention, a material of the metal film is indium (In), tin (Sn) or aluminum (Al).

According to a preferred embodiment of the present invention, the first chroma is substantially between −0.6 and 0.6, and the second chroma is substantially between −0.4 and 2.1.

The film structure of the present invention is formed by using a physical sputtering process with environmental protection property, so that a contaminating organic solvent is not needed in the manufacturing process of the present invention. Therefore, as compared with the conventional spray coating process, the present invention does not cause pollution, thereby conforming to the requirements of Green products.

In addition, the metal film can include a rough surface by sputtering the metal, such as Al, In or Sn, onto a surface of the substrate. The microcosmic structure of the film surface is very rough, so that the incident visible light can be scattered in any directions, and the sputtered substrate has a white surface with metallic luster or a ceramic texture. Further, by applying the film structure of the present invention on a portable communication device, such as a mobile phone, a notebook, a GPS, an earphone, a MP3 player, or an e book, the contrast between the white color of the film structure and the bottom color of the screen can present a three-dimensional effect.

### BRIEF DESCRIPTION OF THE DRAWINGS

The foregoing aspects and many of the attendant advantages of this invention are more readily appreciated as the same become better understood by reference to the following detailed description, when taken in conjunction with the accompanying drawings, wherein:

FIG. 1 is a schematic diagram showing a film structure in accordance with an embodiment of the present invention;

FIG. 2 is a schematic diagram showing the reflectivity testing of a film structure in accordance with an embodiment of the present invention;

FIG. 3 illustrates a partial enlarged view of FIG. 2;

FIG. 4A is an atomic force microscope diagram showing an Sn film in accordance with an embodiment of the present invention;

FIG. 4B illustrates reflection spectra of a conventional Sn film;

FIG. 4C illustrates reflection spectra of an Sn film in accordance with an embodiment of the present invention;

FIG. 5A is an atomic force microscope diagram showing an Al film in accordance with an embodiment of the present invention;

FIG. 5B illustrates reflection spectra of a conventional Al film;

FIG. 5C illustrates reflection spectra of an Al film in accordance with an embodiment of the present invention;

FIG. 6A is an atomic force microscope diagram showing an In film in accordance with an embodiment of the present invention;

FIG. 6B illustrates reflection spectra of a conventional In film;

FIG. 6C illustrates reflection spectra of an In film in accordance with an embodiment of the present invention;

FIG. 7 is an image of a microcosmic tissue of an Sn film sample observed by an atomic force microscope (AFM) in accordance with an embodiment of the present invention;

FIG. 8 is an image of a microcosmic tissue of an Sn film sample observed by a scanning electron microscope (SEM) in accordance with an embodiment of the present invention;

FIG. 9 is an image of a microcosmic tissue of an Al film sample observed by an AFM in accordance with an embodiment of the present invention;

FIG. 10 is an image of a microcosmic tissue of an Al film sample observed by a SEM in accordance with an embodiment of the present invention;

FIG. 11 is an image of a microcosmic tissue of an In film sample observed by an AFM in accordance with an embodiment of the present invention; and

FIG. 12 is an image of a microcosmic tissue of an In film sample observed by a SEM in accordance with an embodiment of the present invention.

### DETAILED DESCRIPTION OF THE PREFERRED EMBODIMENT

The present invention can be embodied in various types of embodiments. One preferred embodiment of the present invention is subsequently illustrated and described. It is understood that the disclosure should be one illustrative of the present invention and do not limit the scope of the present invention to the disclosed specific embodiment.

The color of an object seen by human eye has three qualities. According to the Monsell color system, one color is defined by hue, brightness and chroma. The hue is a color exhibiting the main wavelength reflected by the object, that is a typical description of the color of the seen object. Ten main hues including five main color (red, yellow, green, blue, purple) and combinations of two adjacent main colors are used to represent, for example a red tone and blue-green tone. A colored material reflects or transmits the light in a specific zone in the spectrum, and can emit the light with the wavelength, which can be reflected by the colored material. The brightness is used to indicate the lightness of the color. The brightness also relates to the reflectivity of the object surface, wherein the brightness of the surface is in direct proportion to the product of the received illumination of the surface and the reflectivity. While more lights are reflected by the object surface, the brightness of the object surface is higher and the color of the object is lighter or brighter. The chroma indicates the vividness of the color, i.e. purity or saturation of the color. While the color is purer, the chroma is higher, and the vision stimulation is stromzer. If a pure color with high chroma is gradually diluted by blackening or whitening, the brightness of the blackened color is gradually decreased, the brightness of the whitened color is gradually increased, and the chroma of the blackened color and the whitened color are lowered.

The human eye can recognize the body color of two types. The body color of one type is the color of a self-luminous body. The self-luminous body may be nature, for example, the sun; or the self-luminous body may be artificial, for example a computer display, a fluorescent lamp or a mercury lamp and etc. The body color of the other type is the color of the light reflected and scattered by the body and is recognized by the vision of the human eye. The scattering is in relation to the wavelength and the sizes of the particles of the light. For the lights having the same wavelength, when the particles are small, the light with specific spectra is selectively scattered (referred as Rayleigh Scattering) by the particles. For example, the light with the spectra of the purple tone and blue tone of the visible light is scattered by the air particles (0.001 μm), and the light with the spectra of the red tone and yellow tone of the visible light is scattered by the dust (0.1 μm). When the sizes of the particles are large, various spectra in the range of the visible light can be uniformly scattered (referred as Mie Scattering) by the particles to form the white light.

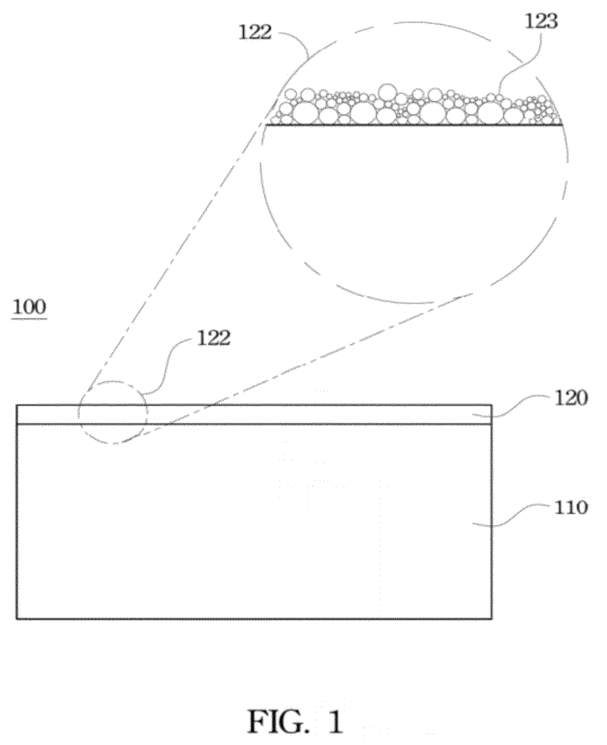

Therefore, the present invention provides a film structure, which can scatter various spectra in the range of the visible light to any directions. Therefore, human eye can observe that the film structure is white and the color of the film structure is not the metallic color. Refer to FIG. 1. FIG. 1 is a schematic diagram showing a film structure 100 in accordance with an embodiment of the present invention. The film structure 100 includes a substrate 110 and a metal film 120. The substrate 110 may include a metal substrate, an alloy substrate, a ceramic substrate, a glass substrate, a semiconductor substrate or a plastic substrate. In a particular embodiment, the metal substrate is a stainless steel. In a particular embodiment, a material of the alloy substrate is selected from a group consisting of Cu, Al, Mg, Ti, Fe, Ni, Cr, Mo and alloys thereof.

In one embodiment, the metal film 120 may be formed on the substrate 100 by various physical vapor deposition methods, such as a sputtering method. In a particular embodiment, the metal film 120 may be formed on the substrate 110 by a vacuum DC magnetron sputtering process. In a particular embodiment, the metal film 120 may be formed on the substrate 110 by a vacuum RF magnetron sputtering process. In one embodiment, the brightness L* of the metal film 120 in the visible light region is between 65 and 95, the chroma a* is between −2.1 and 2.1, and the chroma b* is between −2.1 and 2.1. The brightness L* represents the lightness. A color of the metal film 120 is defined as white while the brightness L* is 100, and a color of the metal film is defined as black while the brightness L* is 0. The hue and the brightness are referred as chroma. If the x-coordinate represents chroma a*, the right of the origin of the x-coordinate is represented by “+a” and is defined as red “R”; and the left of the origin of the x-coordinate is represented by “−a” and is defined as green “G”. If the x-coordinate represents chroma b*, the right of the origin of the x-coordinate is represented by “+b” and is defined as yellow “Y”; and the left of the origin of the x-coordinate is represented by “−b” and is defined as blue “B”. No matter the values of a* and b* are “+”or “−”, while the values of a* and b* are getting larger, the color has more value; and while the values of a* and b* are getting smaller, the color has less value.

In a particular embodiment, the metal film 120 has the brightness L* between 65 and 95, the chroma a* between −0.6 and 0.6, and the chroma b* between −0.4 and 2.1 in the visible light region.

As the partial enlarged view of the portion 122 in FIG. 1, diameters of particles 123 of the metal film 120 deposited on the substrate 110 need to be controlled within a specific range to make the metal film 120 deposited on the substrate 110 include a microcosmic rough surface. If the diameters of the deposited particles 123 are excessively large, the surface formed by the particles 123 is a large flat surface for the visible light. As a result, the incident light is reflected in a fixed direction and cannot be scattered toward any directions, so that the metal film is presented with the original metallic luster, and the metal film cannot be presented with the white luster. If the diameters of the deposited particles 123 are excessively small, the metal film 120 is deposited to include a continuous flat mirror structure. The visible light is reflected by the mirror structure and is not scattered in any directions by the mirror structure, so that the metal film cannot be presented with the white luster but is presented with the color of the metal itself, such as silver of Al, or silver gray of An and In.

In one embodiment, a bottom diameter of the particle 123 of the metal film 120 is substantially between 0.05 μm and 2 μm, and a height of the particle 123 of the metal film 120 is substantially between 0.05 μm and 3 μm. The particles 123 of the metal film 120 are not all sphericity and include various irregular shapes, so that a projection diameter, i.e. the bottom diameter, and the height of the particle 123 are used to define the size of the particle 123. The particles 123 deposited on the surface of the substrate 110 may stack with each other, so that the height of the particle 123 is not directly equal to the roughness of the surface of the metal film 120.

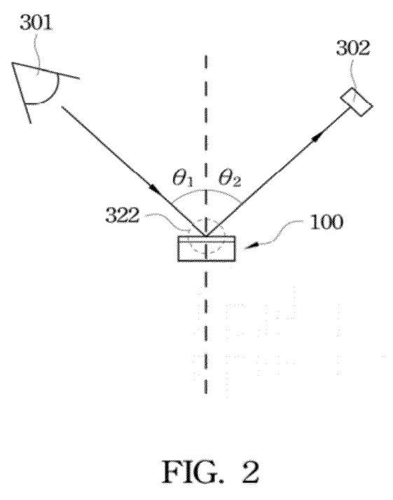

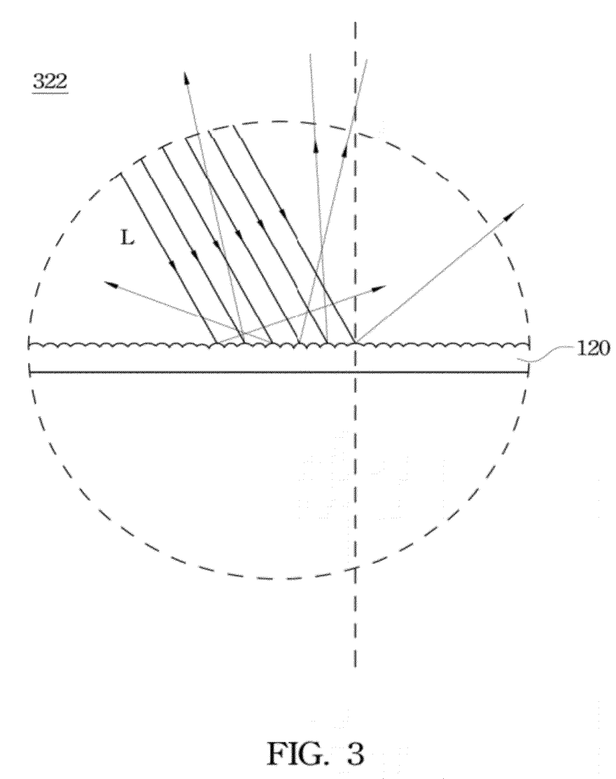

Refer to FIG. 2. FIG. 2 is a schematic diagram showing the reflectivity testing of a film structure 100 in accordance with an embodiment of the present invention. In the present embodiment, an incident angle θ₁ and a reflection angle θ₂ of a testing incident light are fixed. A light source 301 is a special bulb, which can emit infrared rays, visible light and ultraviolet rays. The light source 301 emits a light beam L toward the film structure 100. After the light beam L is reflected by the metal film 120, the light beam L is received by a light sensor 302. The wavelength range measured by the light sensor 302 is between 190 nm and 1000 nm. The microcosmic structure of the surface of the metal film 120 is rough, so that after the light beam L falls on the metal film 120, only a portion of the light beam L is received by the light sensor 302, and the other portion of the light beam L is scattered in different directions, as shown in the partial enlarged view of a portion 322 in FIG. 3. Points on the metal film 120 can respectively scatter the light beam L in different directions. An observer observes at a fixed observation location opposite to the metal film 120, the light received by the observer is an integration of the light scattered by the points of the metal film 120 and uniformly includes the light of various wavelengths. Therefore, when the human eye observes the metal film 120 under the visible light, it can be observed that the metal film 120 is presented with white luster.

The following specifically illustrates the present invention by some practical embodiments, and does not limit the scope of the present invention to the disclosed specific embodiment.

### Embodiment 1

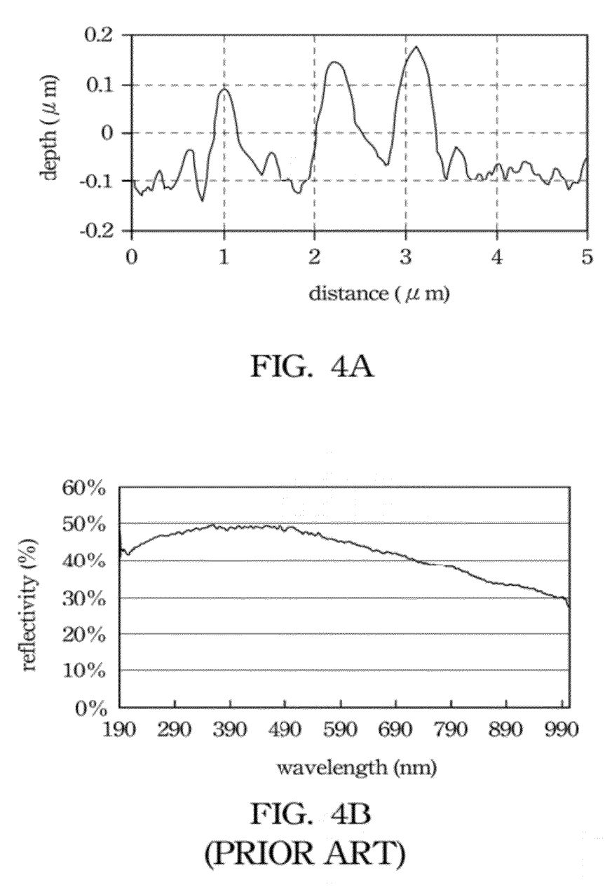

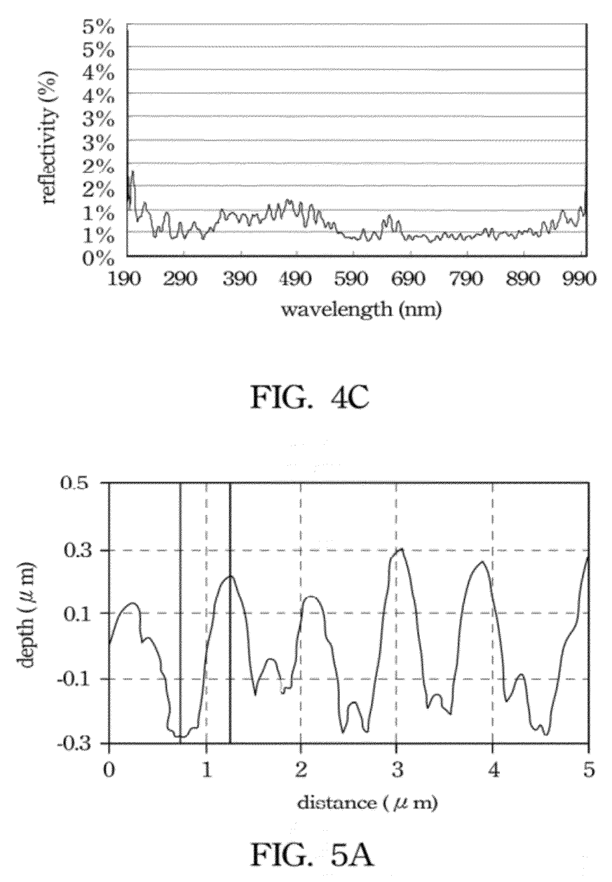

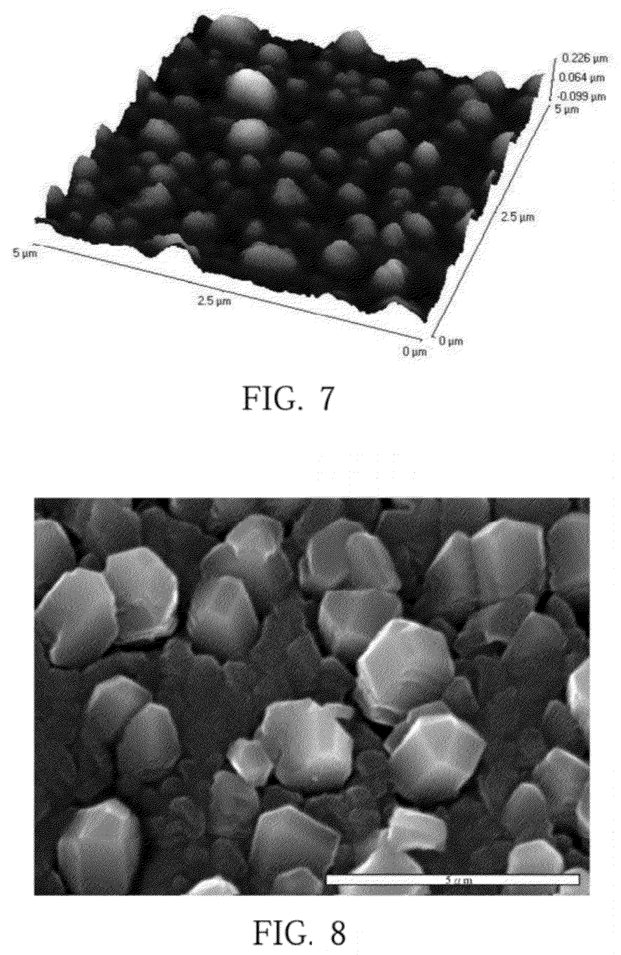

An Sn target is firstly provided. The purity of the Sn target is 99%, and a diameter of the Sn target is six inches. Then, a ceramic substrate having a smooth flat surface is provided. Next, the ceramic substrate is disposed in a vacuum DC magnetron sputtering chamber, and Ar gas is introduced into the chamber, wherein the flow rate of the Ar gas is set to 20 sccm. The material of the Sn target is sputtered onto the ceramic substrate by using a DC magnetron target, wherein the sputtering power is set to 700 watts. The area of the deposited Sn film sample on the ceramic substrate is 25 centimeters*25 centimeters, and the thickness of the Sn film sample is 900 nm. The deposited area and the thickness of the sample are merely used for testing and do not limit the scope of the present invention. The deposited area and thickness do not affect the presented color of the film. Then, the microcosmic tissue of the Sn film sample is observed by an AFM, and the observed image is shown in the FIG. 7. The microcosmic tissue of the Sn film sample is observed by an SEM, and the observed image is shown in the FIG. 8. The flatness of the sample surface is shown in FIG. 4A. The brightness and the chroma of the Sn film sample are further measured to obtain the brightness L*=78.35, the chroma a*=0.35 and the chroma b*=−0.27, and the color of the Sn film sample observed by the human eye under the visible light is white.

FIG. 4B illustrates reflection spectra of a conventional Sn film. FIG. 4C illustrates reflection spectra of an Sn film in accordance with an embodiment of the present invention. The test methods of the reflection spectra in FIG. 4B and FIG. 4C are similar to that shown in FIG. 2, but the incident angle and the reflection angle are two degrees. The conventional film deposited by using an Sn target is a mirror structure, so that the reflectivity of the conventional Sn film for the light with the wavelength between 190 nm and the 1000 nm is between about 30% and about 50%. The Sn film of the embodiment of the present invention is composed of metal particles, each of which has a diameter between about 0.05 μm and 2 μm. The diameters of the metal particles are larger, so that the film surface deposited by the metal particles is uneven, and the surface of the Sn film is rough. The measured reflectivity is approximately lower than 2%, as shown in FIG. 4C. Therefore, the film structure of the embodiment of the present invention can be presented with white luster. When a reflectivity test is performed with the incident angle of 20 degrees, the obtained reflectivity is about 3%. When a reflectivity test is performed with the incident angle of 65 degrees, the obtained reflectivity is about 11%.

### Embodiment 2

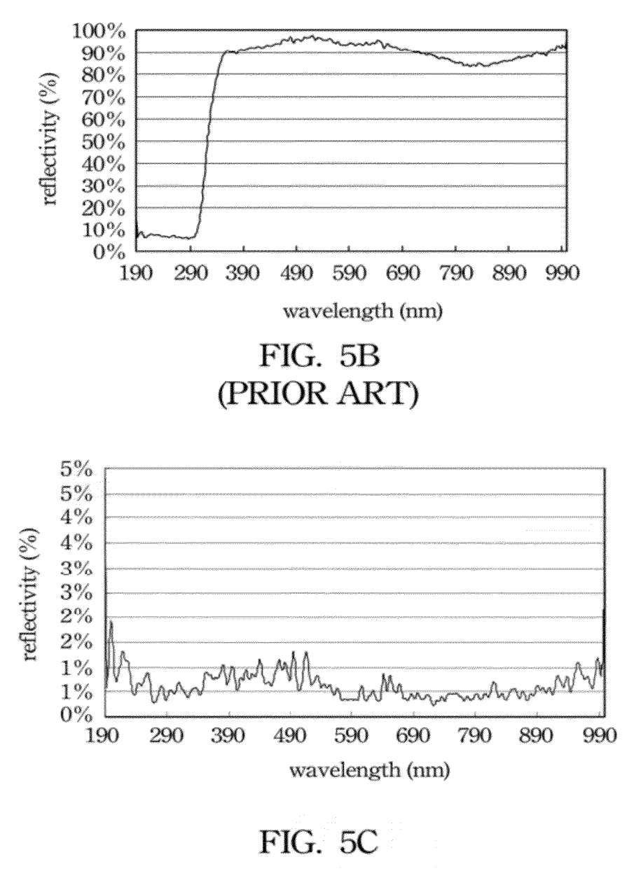

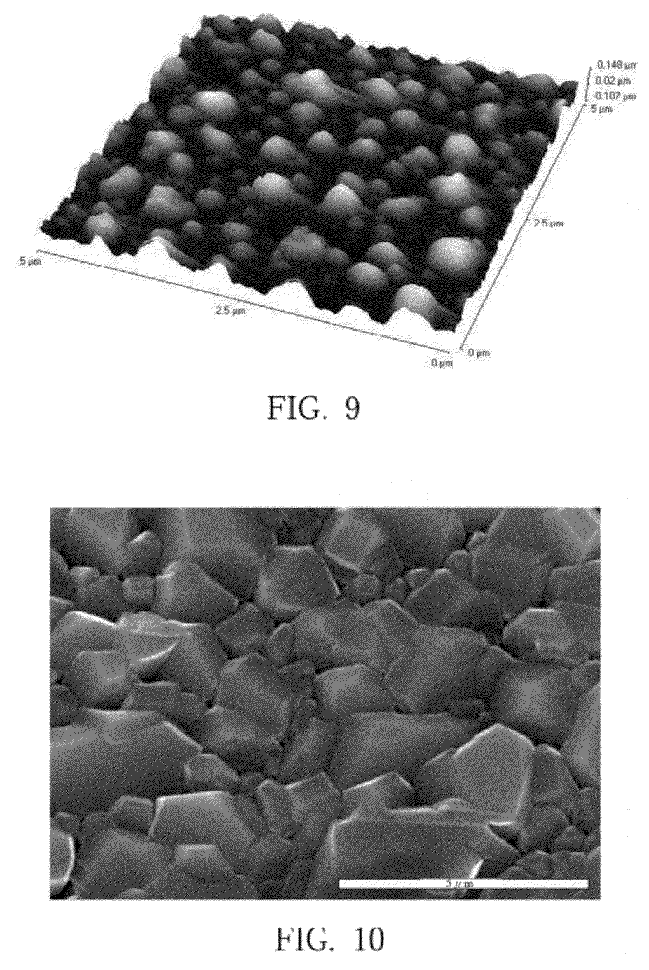

An Al target is firstly provided. The purity of the Al target is 99%, and a diameter of the Al target is two inches. Then, a glass substrate having a smooth flat surface is provided. Next, the glass substrate is disposed in a vacuum magnetron sputtering chamber, and Ar gas is introduced into the chamber, wherein the flow rate of the Ar gas is set to 15 seem. The material of the Al target is sputtered onto the glass substrate by using a DC magnetron target, wherein the sputtering power is set to 50 watts. The area of the deposited Al film sample on the glass substrate is 25 centimeters*25 centimeters, and the thickness of the Al film sample is 1000 nm. The deposited area and the thickness of the sample are merely used for testing and do not limit the scope of the present invention. The deposited area and thickness do not affect the presented color of the film. Then, the microcosmic tissue of the Al film sample is observed by an AFM, and the observed image is shown in the FIG. 9. The microcosmic tissue of the Alfilm sample is observed by an SEM, and the observed image is shown in the FIG. 10. The flatness of the sample surface is shown in FIG. 5A. The brightness and the chroma of the Al film sample are further measured to obtain the brightness L*=94.02, the chroma a*=−0.51 and the chroma b*=0.06, and the color of the Al film sample observed by the human eye under the visible light is white.

FIG. 5B illustrates reflection spectra of a conventional Al film. FIG. 5C illustrates reflection spectra of an Al film in accordance with an embodiment of the present invention. The test methods of the reflection spectra in FIG. 5B and FIG. 5C are similar to that shown in FIG. 2, but the incident angle and the reflection angle are two degrees. The conventional film deposited by using an Al target is a mirror structure, so that the reflectivity of the conventional Al film for the light with the wavelength between 190 nm and the 1000 nm is about 90%. The Al film of the embodiment of the present invention is composed of metal particles, each of which has a diameter between about 0.05 μm and 2 μm. The diameters of the metal particles are larger, so that the film surface deposited by the metal particles is uneven, and the surface of the Al film is rough. The measured reflectivity is approximately lower than 2%, as shown in FIG. 5C. Therefore, the film structure of the embodiment of the present invention can be presented with white luster. When a reflectivity test is performed with the incident angle of 20 degrees, the obtained reflectivity is about 1%. When a reflectivity test is performed with the incident angle of 65 degrees, the obtained reflectivity is about 13%.

It is worthy of note that pure Al is very easy to react with oxygen of the air to form aluminum oxide, so that the surface of the Al film further includes an aluminum oxide film. The aluminum oxide film is almost completely transparent in the visible light range, so that the presented color of the Al film is not affected by the aluminum oxide film and is still white.

### Embodiment 3

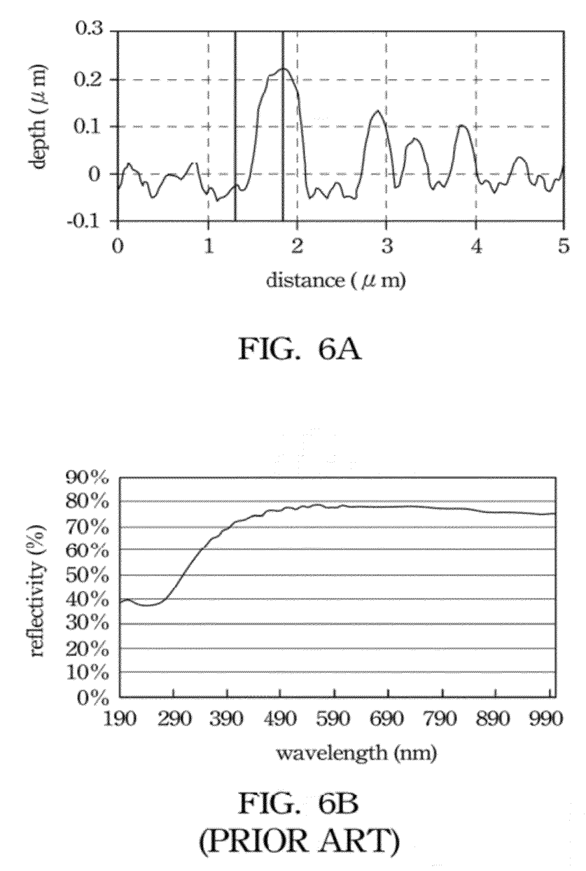

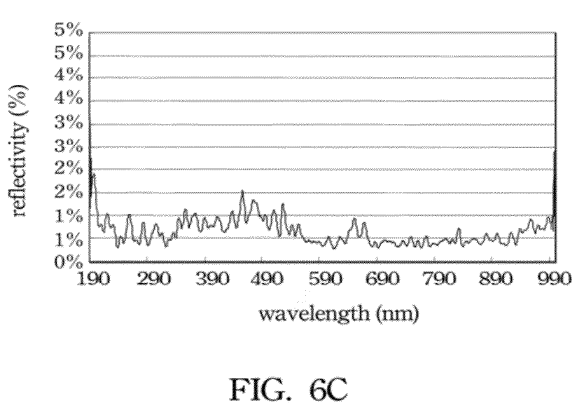

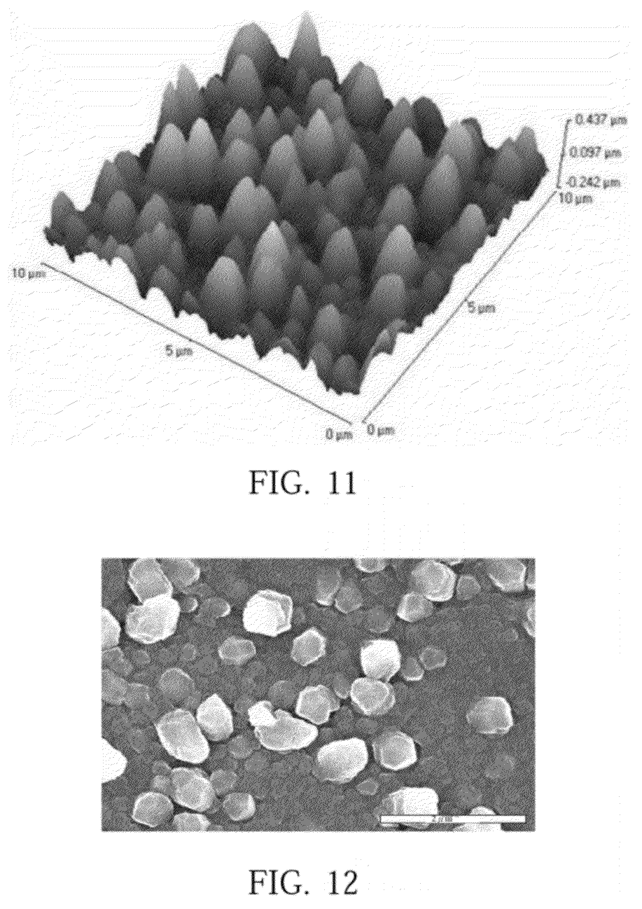

An In target is firstly provided. The purity of the In target is 99%, and a diameter of the In target is six inches. Then, a stainless steel substrate having a smooth flat surface is provided. Next, the stainless steel substrate is disposed in a vacuum magnetron sputtering chamber, and Ar gas is introduced into the chamber, wherein the flow rate of the Ar gas is set to 20 sccm. The material of the In target is sputtered onto the stainless steel substrate by using a DC magnetron target, wherein the sputtering power is set to 500 watts. The area of the deposited In film sample on the stainless steel substrate is 50 centimeters*50 centimeters, and the thickness of the In film sample is 1200 nm. The deposited area and the thickness of the sample are Merely used for testing and do not limit the scope of the present invention. The deposited area and thickness do not affect the presented color of the film. Then, the microcosmic tissue of the In film sample is observed by an AFM, and the observed image is shown in the FIG. 11. The microcosmic tissue of the In film sample is observed by an SEM, and the observed image is shown in the FIG. 12. The flatness of the sample surface is shown in FIG. 6A. The brightness and the chroma of the In film sample are further measured to obtain the brightness L*=79.82, the chroma a*=0.26 and the chroma b*=2.01, and the color of the In film sample observed by the human eye under the visible light is white.

FIG. 6B illustrates reflection spectra of a conventional In film. FIG. 6C illustrates reflection spectra of an In film in accordance with an embodiment of the present invention. The test methods of the reflection spectra in FIG. 68 and FIG. 6C are similar to that shown in FIG. 2, but the incident angle and the reflection angle are two degrees. The conventional film deposited by using an In target is a mirror structure, so that in FIG. 6B, the reflectivity of the conventional In film for the light with the wavelength between 190 nm and the 1000 nm is between about 70% and about 80%. The In film of the embodiment of the present invention is composed of metal particles, each of which has a diameter between about 0.05 μm and 2 μm. The diameters of the metal particles are larger, so that the film surface deposited by the metal particles is uneven, and the surface of the In film is rough. The measured reflectivity is approximately lower than 2%, as shown in FIG. 6C. Therefore, the film structure of the embodiment of the present invention can be presented with white luster. When a reflectivity test is performed with the incident angle of 20 degrees, the obtained reflectivity is about 1%. When a reflectivity test is performed with the incident angle of 65 degrees, the obtained reflectivity is about 4%.

As is understood by a person skilled in the art, the foregoing preferred embodiments of the present invention are illustrative of the present invention rather than limiting of the present invention. It is intended to cover various modifications and similar arrangements included within the spirit and scope of the appended claims, the scope of which should be accorded the broadest interpretation so as to encompass all such modifications and similar structure.

What is claimed is:

1. A film structure, includes:
a substrate; and
a metal film formed on the substrate by a physical vapor deposition method,
wherein a bottom diameter of particles forming the metal film is substantially between 0.05 μm and 2 μm, and a height of the particles of the metal film is substantially between 0.05 μm and 3 μm,
wherein the metal film has a brightness, a first chroma and a second chroma in a visible light region, which includes a wavelength range between 380 nm and 770 nm, the brightness is substantially between 65 and 95, the first chroma is substantially between −2.1 and 2.1, and the second chroma is substantially between −2.1 and 2.1,
wherein a color of the metal film is defined as pure white while the brightness of the color is 100, and a color of the metal film is defined as pure black while the brightness of the color is 0; a color of the metal film is defined as red while the first chroma is a positive value, and a color of the metal film is defined as green while the first chroma is a negative value; and a color of the metal film is defined as yellow while the second chroma is a positive value, and a color of the metal film is defined as blue while the second chroma is a negative value, and
wherein a color of the metal film has more value while the first chroma and the second chroma are getting larger, and a color of the metal film has less value while the first chroma and the second chroma are getting smaller.

2. The film structure according to claim 1, wherein the substrate is a metal substrate, an alloy substrate, a ceramic substrate, a glass substrate, a semiconductor substrate or a plastic substrate.

3. The film structure according to claim 2, wherein the metal substrate is a stainless steel substrate.

4. The film structure according to claim 2, wherein a material of the alloy substrate is selected from a group consisting of Cu, Al, Mg, Ti, Fe, Ni, Cr, Mo and alloys thereof.

5. The film structure according to claim 1; wherein the physical vapor deposition method is a vacuum DC magnetron sputtering method or a vacuum RF magnetron sputtering method.

6. The film structure according to claim 1, wherein a material of the metal film is selected from a group consisting of In, Sn and Al.

7. The film structure according to claim 1, wherein the first chroma is substantially between −0.6 and 0.6, and the second chroma is substantially between −0.4 and 2.1.

8. A method for manufacturing a film structure, wherein the film structure is formed by a physical vapor deposition method, and the method includes:
providing a substrate; and
depositing a metal film on the substrate by using a metal target,
wherein a bottom diameter of particles forming the metal film is substantially between 0.05 μm and 2 μm, and a height of the particles of the metal film is substantially between 0.05 μm and 3 μm,
wherein the metal film has a brightness, a first chroma and a second chroma in a visible light region, which includes a wavelength range between 380 nm and 770 nm, the brightness is substantially between 65 and 95, the first chroma is substantially between −2.1 and 2.1, and the second chroma is substantially between −2.1 and 2.1,
wherein a color of the metal film is defined as pure white while the brightness of the color is 100, and a color of the metal film is defined as pure black while the brightness of the color is 0; a color of the metal film is defined as red while the first chroma is a positive value, and a color of the metal film is defined as green while the first chroma is a negative value; and a color of the metal film is defined as yellow while the second chroma is a positive value, and a color of the metal film is defined as blue while the second chroma is a negative value, and
wherein a color of the metal film has more value while the first chroma and the second chroma are getting larger, and a color of the metal film has less value while the first chroma and the second chroma are getting smaller.

9. The method according to claim 8, wherein the physical vapor deposition method is a vacuum DC magnetron sputtering method or a vacuum RF magnetron sputtering method.

10. The method according to claim 8, wherein the substrate is a metal substrate, an alloy substrate, a ceramic substrate, a glass substrate, a semiconductor substrate or a plastic substrate.

11. The method according to claim 8, wherein the metal target is selected from a group consisting of an Al target, an Sn target and an In target.

12. The method according to claim 11, wherein purity of each of the Al target, the Sn target and the In target is 99%.

13. The method according to claim 8, wherein the first chroma is substantially between −0.6 and 0.6, and the second chroma is substantially between−0.4 and 2.1.
